(19) United States
(12) Patent Application Publication
(10) Pub. No.: US 2026/0287685 A1
(43) Pub. Date: Sep. 24, 2026

(54) SYSTEMS AND METHODS FOR MAGNETOMETER CALIBRATION

(71) Applicant: STMicroelectronics International N.V., Geneva (CH)

(72) Inventor: Andrea Lorenzo VITALI, San Jose, CA (US)

(21) Appl. No.: 18/956,935

(22) Filed: Nov. 22, 2024

(51) Int. Cl. G01R 33/00; G01R 33/02; G01R 35/00

(52) U.S. Cl. CPC G01R 33/0023; G01R 35/005; G01R 33/0206

(57) ABSTRACT

In accordance with various embodiments of the present disclosure, a method for calibrating a 3-axis magnetometer is provided. In some embodiments, the method comprises receiving magnetic field data collected as a magnetometer is moved in only two dimensions in a circle or a partial circle around a fixed vertical axis of rotation, the magnetic field data collected at a plurality of locations along the circle or the partial circle; fitting a circle to the magnetic field data; determining an X coordinate and a Y coordinate of a center of the fitted circle; and providing the X coordinate and the Y coordinate of the center of the fitted circle to the magnetometer for use as, respectively, an X-axis HI offset and a Y-axis HI offset for performing HI offset compensation.

### FIELD OF THE INVENTION

Example embodiments of the present disclosure relate generally to magnetometers and, more specifically, to calibrating magnetometers.

### BACKGROUND

Many devices, such as mobile devices (smart phones, etc.) have an e-compass capability. Such e-compass capability requires the device to have a magnetometer.

Magnetic measurements from such a magnetometer are subjected to distortion. These distortions are considered to fall in one of two categories: hard iron (HI) or soft iron (SI). Hard iron distortions are created by objects that produce a magnetic field, such as a speaker or piece of magnetized iron. If the piece of magnetic material is physically attached to the mobile device, then this type of hard iron distortion will cause a permanent bias in the sensor output. Soft iron distortions are considered deflections or alterations in the existing magnetic field. These distortions will stretch or distort the magnetic field depending upon which direction the field acts relative to the magnetometer. This type of distortion is commonly caused by metals such as nickel and iron, such as in surrounding structures.

To offset this HI and SI distortion, the magnetometer needs to be calibrated. Calibration methods that have been used include Zero Gauss Chambers to support the measurement of the HI offset or Helmholtz coils that support the tumble calibration. However, these methods require expensive equipment and generally cannot be utilized in the field after the device is installed. Other methods of magnetometer calibration typically require 3D motion and in particular, rotating the device around at least two different axes, and taking data readings. The HI offset and SI scaling matrix are estimated by fitting a 3D sphere/ellipsoid to the data points. Unfortunately, this is not always possible as the magnetometer may be mounted on a device that can only rotate around one axis (i.e., in two dimensions). Such devices may be, for example, mounted on a pole (e.g., certain types of satellite antennas) and only able to move in two dimensions (i.e., around the pole).

Applicant has identified many technical challenges and difficulties associated with magnetometer calibration. Through applied effort, ingenuity, and innovation, Applicant has solved problems related to magnetometer calibration by developing solutions embodied in the present disclosure, which are described in detail below.

### BRIEF SUMMARY

Various embodiments described herein related to systems and methods for magnetometer calibration.

In accordance with various embodiments of the present disclosure, a method for calibrating a 3-axis magnetometer is provided. In some embodiments, the method comprises receiving magnetic field data collected as a magnetometer is moved in only two dimensions in a circle or a partial circle around a fixed vertical axis of rotation, the magnetic field data collected at a plurality of locations along the circle or the partial circle; if only hard iron (HI) offset compensation of the magnetometer is desired, the method comprises: (a) fitting a circle to the magnetic field data; (b) determining an X coordinate and a Y coordinate of a center of the fitted circle; and (c) providing the X coordinate and the Y coordinate of the center of the fitted circle to the magnetometer for use as, respectively, an X-axis HI offset and a Y-axis HI offset for performing HI offset compensation; if only HI offset compensation and soft iron (SI) scaling compensation are desired, the method comprises: (a) fitting an ellipse to the magnetic field data; (b) determining an X coordinate and a Y coordinate of a center of the fitted ellipse; (c) determining an X-axis scaling factor and a Y-axis scaling factor; (d) providing the X-axis scaling factor and the Y-axis scaling factor to the magnetometer for performing SI scaling compensation; (e) using the X-axis scaling factor and the Y-axis scaling factor to determine an X-axis HI offset and a Y-axis HI offset; and (f) providing the X-axis HI offset and the Y-axis HI offset to the magnetometer for performing HI offset compensation.

In some embodiments, if HI offset compensation, SI scaling compensation, and SI rotation compensation are desired, the method further comprises, prior to determining an X coordinate and a Y coordinate of a center of the fitted ellipse: fitting a plane to the magnetic field data; de-rotating the magnetic field data to a horizontal plane; fitting an ellipse to the magnetic field data de-rotated to the horizontal plane, and aligning a minor axis and a major axis of the fitted ellipse to an X-axis and a Y-axis.

In some embodiments, the method further comprises determining an X-axis radius and a Y-axis radius of the fitted ellipse. Determining the X-axis scaling factor comprises dividing r by the X-axis radius. Determining the Y-axis scaling factor comprises dividing r by the Y-axis radius. R is an arbitrary reference radius or r is a true expected radius based on a magnetic field strength and on a magnetic inclination at a location of the magnetometer.

In some embodiments, using the X-axis scaling factor and the Y-axis scaling factor to determine an X-axis HI offset and a Y-axis HI offset comprises: applying the X-axis scaling factor and the Y-axis scaling factor to the fitted ellipse to obtain a corresponding offset circle; and determining an X coordinate and a Y coordinate of a center of the corresponding offset circle. The X coordinate and the Y coordinate of the center of the corresponding offset circle is provided to the magnetometer for use as, respectively, an X-axis HI offset and a Y-axis HI offset for performing HI offset compensation.

In some embodiments, using the X-axis scaling factor and the Y-axis scaling factor to determine an X-axis HI offset and a Y-axis HI offset comprises: dividing the X coordinate of the center of the fitted ellipse by the X-axis scaling factor to determine the X-axis HI offset; and dividing the Y coordinate of the center of the fitted ellipse by the Y-axis scaling factor to determine the Y-axis HI offset.

In some embodiments, collecting magnetic field data at a plurality of locations along the circle or the partial circle comprises collecting a plurality of magnetic field data points at each of one or more of the plurality of locations along the circle or the partial circle and averaging the plurality of magnetic field data points collected at each of the one or more of the plurality of locations along the circle or the partial circle.

In accordance with various embodiments of the present disclosure, a method for calibrating a 3-axis magnetometer is provided. In some embodiments, the method comprises (i) receiving magnetic field data collected as a magnetometer is moved in only two dimensions in a circle or a partial circle around a fixed, non-vertical axis of rotation, the magnetic field data collected at a plurality of locations along the circle or the partial circle; (ii) if only hard iron (HI) offset compensation of the magnetometer is desired, the method comprises: (a) fitting a plane to the magnetic field data; (b) de-rotating the magnetic field data to a horizontal plane; (c) fitting a circle to the magnetic field data de-rotated to the horizontal plane; (d) determining a radius of the fitted circle; (e) determining an X coordinate, a Y coordinate, and a Z coordinate of a center of the fitted circle; (f) rotating the fitted circle back to its original plane; (f) determining a 3-element unity vector corresponding to a normal of the original plane, the 3-element unity vector comprising a, b, and c elements; (g) if a magnetic field strength at a location of the magnetometer is known, determining an X-axis HI offset, a Y-axis HI offset, and a Z-axis HI offset using the 3-element unity vector corresponding to the normal of the original plane and the magnetic field strength at the location of the magnetometer; (h) if a magnetic field strength at a location of the magnetometer is not known, determining an X-axis HI offset, a Y-axis HI offset, and a Z-axis HI offset using the 3-element unity vector corresponding to the normal of the original plane and an estimate of the magnetic field strength at the location of the magnetometer; and (i) providing the X-axis HI offset, the Y-axis HI offset, and the Z-axis HI offset to the magnetometer for performing HI offset compensation; (iii) if only HI offset compensation and soft iron (SI) scaling compensation are desired, the method comprises: (a) fitting a plane to the magnetic field data; (b) de-rotating the magnetic field data to a horizontal plane; (c) fitting an ellipse to the magnetic field data; (d) determining an X coordinate and a Y coordinate of a center of the fitted ellipse; (e) determining a major axis radius and a minor axis radius of the fitted ellipse; (f) rotating the fitted ellipse back to its original plane; (g) determining a height, width, and depth of a bounding box around the fitted ellipse rotated back to its original plane; (h) determining a height, width, and depth of an ideal bounding box using the magnetic field strength at the location of the magnetometer; (i) determining an X-axis scaling factor, a Y-axis scaling factor, and a Z-axis scaling factor based on dividing, respectively, the height, width, and depth of the bounding box around the fitted ellipse rotated back to its original plane by the height, width, and depth of the ideal bounding box; (j) providing the X-axis scaling factor, the Y-axis scaling factor, and the Z-axis scaling factor to the magnetometer for performing SI scaling compensation; (k) using the X-axis scaling factor, the Y-axis scaling factor, and the Z-axis scaling factor to determine an X-axis HI offset, a Y-axis HI offset, and a Z-axis HI offset; and (l) providing the X-axis HI offset, the Y-axis HI offset, and the Z-axis HI offset to the magnetometer for performing HI offset compensation.

In accordance with various embodiments of the present disclosure, a system for calibrating a 3-axis magnetometer is provided. In some embodiments, the system comprises a first device comprising processing circuitry configured to: (i) if only hard iron (HI) offset compensation of the magnetometer is desired, the processing circuitry is configured to: (a) fit a circle to magnetic field data collected as a magnetometer is moved in only two dimensions in a circle or a partial circle around a fixed vertical axis of rotation; (b) determine an X coordinate and a Y coordinate of a center of the fitted circle; and (c) provide the X coordinate and the Y coordinate of the center of the fitted circle to the magnetometer for use as, respectively, an X-axis HI offset and a Y-axis HI offset for performing HI offset compensation; and (ii) if only HI offset compensation and soft iron (SI) scaling compensation are desired, the processing circuitry is configured to: (a) fit an ellipse to the magnetic field data; (b) determine an X coordinate and a Y coordinate of a center of the fitted ellipse; (c) determine an X-axis scaling factor and a Y-axis scaling factor; (d) provide the X-axis scaling factor and the Y-axis scaling factor to the magnetometer for performing SI scaling compensation; (e) use the X-axis scaling factor and the Y-axis scaling factor to determine an X-axis HI offset and a Y-axis HI offset; and (f) provide the X-axis HI offset and the Y-axis HI offset to the magnetometer for performing HI offset compensation.

The above summary is provided merely for purposes of summarizing some example embodiments to provide a basic understanding of some aspects of the disclosure. Accordingly, it will be appreciated that the above-described embodiments are merely examples and should not be construed to narrow the scope or spirit of the disclosure in any way. It will also be appreciated that the scope of the disclosure encompasses many potential embodiments in addition to those here summarized, some of which will be further described below.

### BRIEF DESCRIPTION OF THE DRAWINGS

The description of the illustrative embodiments may be read in conjunction with the accompanying figures. It will be appreciated that, for simplicity and clarity of illustration, elements illustrated in the figures have not necessarily been drawn to scale, unless described otherwise. For example, the dimensions of some of the elements may be exaggerated relative to other elements, unless described otherwise. Embodiments incorporating teachings of the present disclosure are shown and described with respect to the figures presented herein, in which:

FIG. 1 is a block diagram of an example system for magnetometer calibration, in accordance with some embodiments of the present disclosure;

FIG. 2 is a block diagram of an example system for magnetometer calibration, in accordance with some alternative embodiments of the present disclosure;

FIG. 3 is a block diagram of an example system for magnetometer calibration, in accordance with some alternative embodiments of the present disclosure;

FIGS. 4A and 4B illustrate magnetic field data collected from a magnetometer rotating about a vertical axis that is, respectively, undistorted and distorted by HI offsets;

FIGS. 5A and 5B illustrate magnetic field data collected from a magnetometer rotating about a vertical axis that is, respectively, undistorted and distorted by HI offsets and SI scaling;

FIGS. 6A and 6B illustrate magnetic field data collected from a magnetometer rotating about a vertical axis that is, respectively, undistorted and distorted by HI offsets, SI scaling, and SI rotation; and

FIGS. 7A and 7B illustrate magnetic field data collected from a magnetometer rotating about a non-vertical axis that is, respectively, undistorted and distorted by HI offsets.

### DETAILED DESCRIPTION OF THE INVENTION

Some embodiments of the present disclosure will now be described more fully hereinafter with reference to the accompanying drawings, in which some, but not all embodiments of the disclosure are shown. Indeed, these disclosures may be embodied in many different forms and should not be construed as limited to the embodiments set forth herein; rather, these embodiments are provided so that this disclosure will satisfy applicable legal requirements. Like numbers refer to like elements throughout.

As used herein, terms such as “front,” “rear,” “top,” etc. are used for explanatory purposes in the examples provided below to describe the relative position of certain components or portions of components. Furthermore, as would be evident to one of ordinary skill in the art in light of the present disclosure, the terms “substantially” and “approximately” indicate that the referenced element or associated description is accurate to within applicable engineering tolerances.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” and the like generally mean that the particular feature, structure, or characteristic following the phrase may be included in at least one embodiment of the present disclosure, and may be included in more than one embodiment of the present disclosure (importantly, such phrases do not necessarily refer to the same embodiment).

The word “example” or “exemplary” is used herein to mean “serving as an example, instance, or illustration.” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments, or it may be excluded.

Embodiments of the present disclosure involve the calibration of 3-axis vector magnetometers (hereinafter “magnetometers”) that measure the direction of a magnetic field in three axes and provide three numbers (X, Y, Z) that express the magnetic field in each of the three axes.

Providing e-compass capability is a typical application of a vector magnetometer. A 3-axis accelerometer and a 3-axis magnetometer are utilized. The accelerometer measures the orientation with respect the vertical gravity vector to support the computation of roll and pitch angles (angles of rotation around X and Y, where 0 means the device is in the horizontal plane). The magnetometer measures the orientation of the geomagnetic field to support the computation of the yaw angle (angle of rotation around Z, where 0 means the device is oriented towards the magnetic north). Magnetometer measurements must be corrected to eliminate measurements errors, also known as hard-iron and soft-iron effect, and are then compensated for roll and pitch. After compensating for roll and pitch, the yaw angle can be computed by looking at the ratio of X and Y measurements (note that because of this, the common scale or unit of measurement does not matter). Finally, the heading (angle with respect to geographic north) can be computed from the yaw by adding the local magnetic declination (difference between magnetic and geographic north).

The formulas that are conventionally applied to correct magnetometer measurements are the following: tempY=MagY cos(roll)−MagZ sin(roll); tempZ=MagY sin(roll)+MagZ cos(roll); tempX=MagX cos(pitch)+tempZ sin(pitch); Yaw=atan2(−tempY, tempX). In these equations, tempX, tempY, and tempZ represent intermediate results (quantities reused multiple times in other computations) and MagX, MagY, and MagZ represent the magnetometer readings in these axes. The ratio of tempY and tempX is linked to the angle the atan( ) function, here atan2( ) is utilized to cover the full +/−180 degree range. It should be noted that when roll and pitch are both 0, tempY=MagY, tempZ=MagZ, tempX=MagX, and Yaw=atan(−MagY, MagX) with no dependence on MagZ. The dependence on MagZ increases with the roll and pitch angle.

The geomagnetic field varies over the surface of the earth, with its strength (vector norm) varying from a minimum of 25 uT (microteslas) to a maximum of 65 uT. Detailed geomagnetic maps are available, which also include magnetic declination (angle with respect to geographic north) and inclination (angle with respect to the horizontal plane).

Magnetometers are sensitive to all magnetic fields, and they measure the sum of all fields present at their location. Beyond the geomagnetic field, other fields may be present: permanent fields of magnets (example: magnets in speakers); induced fields in ferromagnetic materials (example: iron or steel); and fields generated by current flows (example: power supply wires).

Hard-iron effects come from permanent fields, fields field induced by them in nearby ferromagnetic materials, and generated fields, and are all added on top of the geomagnetic field. HI effects can be seen as a spurious offset that must be subtracted. These offsets do not change with the orientation of the device which utilizes the magnetometer because the sources of the offset are on the device itself (e.g., the speaker is on the same board where the magnetometer is). As such, the relative position of the source with respect to the magnetometer is not going to change when the device is moved around. The HI effects can be expressed by the following: MagX=GeoMagX+OfsX; MagY=GeoMagY+OfsY; and MagZ=GeoMagZ+OfsZ, in which MagX, MagY, and MagZ the magnetometer readings in these axes, GeoMagX, GeoMagY, and GeoMagZ represent the geomagnetic field in these axes, and OfsX, OfsY, and OfsZ represent the HI offsets in these axes.

Soft-iron effects come from all fields induced in nearby ferromagnetic materials by the geomagnetic field. SI effects do change when the device with the magnetometer is moved around because the source of the magnetization is not on the device. Rather, the earth magnetic field is ‘captured’ and ‘altered’ by the soft-iron materials on the board of the device. This effect can be modeled by axes scaling and axes cross-talking, which can be represented by 6 coefficients in a 3×3 symmetric matrix as follows:

$$MagX = C 1 xx GeoMagX + C 2 yx GeoMagY + C 3 zx GeoMagZ + OfsX$$

$$MagY = C 2 yx GeoMagX + C 3 yy GeoMagY + G 4 zy GeoMagZ + OfsY$$

$$MagZ = C 5 zx GeoMagX + C 4 zy GeoMagY + C 6 zz GeoMagZ + OfsZ$$

The 3×3 symmetric matrix can be decomposed into 3 scaling coefficients (for X, Y, and Z) and a 3×3 rotation matrix with 3 degrees of freedom (for the 3 rotation angles around X, Y, and Z).

Calibrating a magnetometer at the factory is not useful, because what matters is the magnetic environment in which the magnetometer is installed. Calibration is therefore always required after installing the magnetometer in a device, and after installing the device in its final location. One approach that has been used for magnetometer calibration is sphere or ellipsoid fitting in which measurements are taken while the device is rotated in 3-D space. If there are no measurement errors, the data points will be located on the surface of a sphere centered at the origin. If there are hard-iron effects, the sphere will offset from the origin. If there are soft-iron effects, the surface will be an ellipsoid (this is a result of what is termed SI scaling), possibly rotated (this is a result of what is termed SI rotation). This type of calibration is very inexpensive but requires the capability to move the device around at least two different axes (i.e., in three dimensions). However, this may not always be possible. For example, a device installed on a vertical pole that can only swing around the vertical pole.

Various embodiments of the present disclosure overcome the above technical challenges and difficulties and provide various technical improvements and advantages based on, for example, but not limited to, providing example systems and methods for calibrating a magnetometer that require only partial rotation around one axis. Thus, in various embodiments, the data points will describe a 2D circle or ellipse embedded in the 3D space. In this regard, the systems and methods for calibrating a magnetometer of embodiments of the disclosure are referred to herein as providing “2D” calibration (as opposed to “3D” for the conventional sphere/ellipsoid fitting).

Various embodiments of the present disclosure enable magnetometer calibration by executing a full or partial rotation around one axis. In various embodiments, a full rotation is not needed but increases the calibration accuracy. In various embodiments, a few evenly spaced magnetic field data points obtained by stopping at such points and averaging for a longer time provide better accuracy as compared to more data points obtained by stopping and averaging for a shorter time, and the memory required to store and process the data points is reduced.

Various embodiments of the present disclosure are described herein in relation to six different calibration scenarios, as follows: Case 1—vertical rotation axis, HI (offset) compensation only; Case 2—vertical rotation axis, HI (offset) and diagonal of SI (scaling factors) compensation; Case 3—vertical rotation axis, HI (offset) and full SI (scaling and rotation) compensation; Case 4—generic rotation axis, HI (offset) compensation only; Case 5—generic rotation axis, HI (offset) and diagonal of SI (scaling factors) compensation; and Case 6—generic rotation axis, HI (offset) and full SI (scaling and rotation) compensation.

Various embodiments of the present disclosure involve rotating a magnetometer (or more typically rotating a device containing a magnetometer, such as a pole-mounted antenna) in two dimensions around a fixed axis (which may be vertical or non-vertical) (e.g., a pole upon which an antenna is mounted) and collecting magnetic field data. The collected magnetic field data is then used with one or more of the various algorithms described herein to obtain compensation factors that can be used to calibrate the magnetometer. Such compensation factors include HI offsets, SI scaling factors, and SI rotation factors.

In various embodiments, all of the operations may be performed within the device containing the magnetometer. In other embodiments, some parts of the operations may be performed within the device containing the magnetometer and some parts of the operations may be performed within a separate calibration device (e.g., a smart phone, tablet, or the like). As described in detail below, knowing the norm of the local geomagnetic field (typically indicated as “B” or “B norm”) and the magnetic inclination at the location of the magnetometer is desirable in some of the compensation scenarios and required in some of the compensation scenarios. Thus, in some embodiments, either the device containing the magnetometer or the separate calibration device must be able to determine the B norm and magnetic inclination at the location of the device containing the magnetometer.

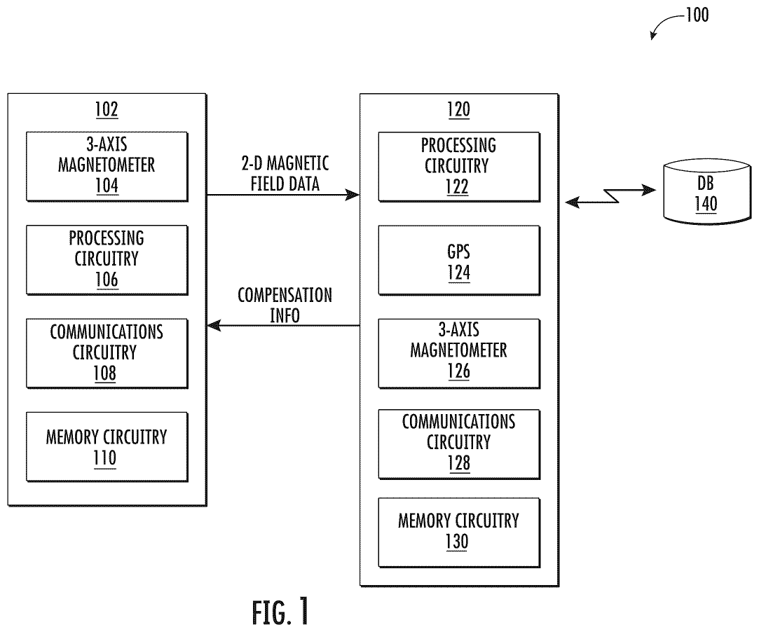

FIGS. 1-3 illustrate three different systems in which various embodiments of the present disclosure may be performed. FIG. 1 illustrates a system 100 comprising a device 102 containing a magnetometer to be calibrated (hereinafter termed a “magnetometer device”) (e.g., antenna) and a calibration device 120 (e.g., a smart phone, tablet, or the like). In the illustrated embodiment, the magnetometer device 102 comprises a 3-axis magnetometer 104 to be calibrated, processing circuitry 106, communications circuitry 108, and memory circuitry 110. In various embodiments, the processing circuitry 106 is configured to execute instructions stored in the memory circuitry 110, and the communications circuitry 108 enables the magnetometer device 102 to communicate with other devices such as the calibration device 120. In various embodiments, the magnetometer device 102 may not comprise all of the components illustrated in FIG. 1.

In the illustrated embodiment, the calibration device 120 comprises processing circuitry 122, GPS circuitry 124, a 3-axis magnetometer 126 to be used in the calibration process, communications circuitry 128, and memory circuitry 130. The calibration device 120 may communicate with a database 140. In various embodiments, the processing circuitry 122 is configured to execute instructions stored in the memory circuitry 130, the communications circuitry 128 enables the calibration device 120 to communicate with other devices such as the magnetometer device 102, the GPS circuitry 124 enables the calibration device 120 to determine its location (and therefore the location of the magnetometer device 102 when the devices are co-located), and the 3-axis magnetometer 126 may be used in the calibration process. In various embodiments, the calibration device 120 may not comprise all of the components illustrated in FIG. 1.

In the embodiment of FIG. 1, the magnetometer device 102 is rotated around a fixed axis, two-dimensional magnetic field data is collected, and the magnetic field data is provided to the calibration device 120. In the embodiment of FIG. 1, the calibration device 120 performs one or more of the algorithms described below to determine the required HI and/or SI compensation factors and provides the determined compensation factors to the magnetometer device 102 to enable calibration of the 3-axis magnetometer 104.

In the embodiment of FIG. 1, if the local B norm and/or magnetic inclination is required, the calibration device 120 may obtain the local B norm and/or magnetic inclination either of two ways. First, the calibration device 120 may obtain the local B norm and/or magnetic inclination by determining the longitude/latitude coordinates of the calibration device 120 using the GPS circuitry 124 and obtaining the local B norm and/or magnetic inclination corresponding to the determined longitude/latitude from the database 140 (which may be, for example, any one of several online databases). Second, the calibration device 120 may obtain the local B norm and/or magnetic inclination by movement of the calibration device 120 (and therefore of the 3-axis magnetometer 126) in three dimensions (i.e., by performing a calibration of the 3-axis magnetometer 126 of the calibration device 120).

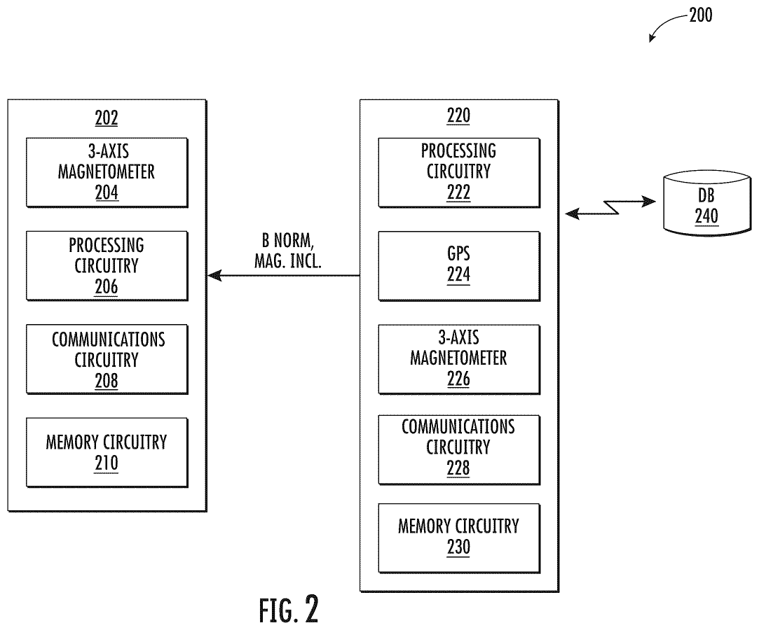

FIG. 2 illustrates a system 200 comprising a device 202 containing a magnetometer to be calibrated (hereinafter termed a “magnetometer device”) (e.g., antenna) and a calibration device 220 (e.g., a smart phone, tablet, or the like). In the illustrated embodiment, the magnetometer device 202 comprises a 3-axis magnetometer 204 to be calibrated, processing circuitry 206, communications circuitry 208, and memory circuitry 210. In various embodiments, the processing circuitry 206 is configured to execute instructions stored in the memory circuitry 210, and the communications circuitry 208 enables the magnetometer device 202 to communicate with other devices such as the calibration device 220. In various embodiments, the magnetometer device 202 may not comprise all of the components illustrated in FIG. 2.

In the illustrated embodiment, the calibration device 220 comprises processing circuitry 222, GPS circuitry 224, a 3-axis magnetometer 226 to be used in the calibration process, communications circuitry 228, and memory circuitry 230. The calibration device 220 may communicate with a database 240. In various embodiments, the processing circuitry 222 is configured to execute instructions stored in the memory circuitry 230, the communications circuitry 228 enables the calibration device 220 to communicate with other devices such as the magnetometer device 202, the GPS circuitry 224 enables the calibration device 220 to determine its location (and therefore the location of the magnetometer device 202 when the devices are co-located), and the 3-axis magnetometer 226 may be used in the calibration process. In various embodiments, the calibration device 220 may not comprise all of the components illustrated in FIG. 2.

In the embodiment of FIG. 2, the magnetometer device 202 is rotated around a fixed axis, two-dimensional magnetic field data is collected, and the magnetometer device 202 performs one or more of the algorithms described below to determine the required HI and/or SI compensation factors and uses the determined compensation factors to perform calibration of the 3-axis magnetometer 204.

In the embodiment of FIG. 2, if the local B norm and/or magnetic inclination is required, the magnetometer device 202 obtains the local B norm and/or magnetic inclination from the calibration device 220. In various embodiments, the calibration device 220 may obtain the local B norm and/or magnetic inclination either of two ways. First, the calibration device 220 may obtain the local B norm and/or magnetic inclination by determining the longitude/latitude coordinates of the calibration device 220 using the GPS circuitry 224 and obtaining the local B norm and/or magnetic inclination corresponding to the determined longitude/latitude from the database 240 (which may be, for example, any one of several online databases). Second, the calibration device 220 may obtain the local B norm and/or magnetic inclination by movement of the calibration device 220 (and therefore of the 3-axis magnetometer 226) in three dimensions (i.e., by performing a calibration of the 3-axis magnetometer 226 of the calibration device 220).

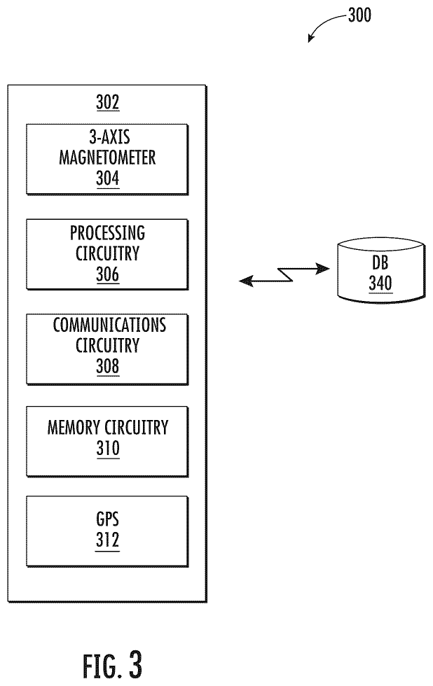

FIG. 3 illustrates a system 300 comprising a device 302 containing a magnetometer to be calibrated (hereinafter termed a “magnetometer device”) (e.g., antenna). In the illustrated embodiment, the magnetometer device 302 comprises a 3-axis magnetometer 204 to be calibrated, processing circuitry 306, communications circuitry 308, memory circuitry 310, and GPS circuitry 312. In various embodiments, the processing circuitry 306 is configured to execute instructions stored in the memory circuitry 310, the communications circuitry 308 enables the magnetometer device 302 to communicate with other devices such as the database 340, and the GPS circuitry 312 enables the magnetometer device 302 to determine its location. In various embodiments, the magnetometer device 302 may not comprise all of the components illustrated in FIG. 3. In the embodiment of FIG. 3, there is no separate calibration device.

In the embodiment of FIG. 3, the magnetometer device 302 is rotated around a fixed axis, two-dimensional magnetic field data is collected, and the magnetometer device 302 performs one or more of the algorithms described below to determine the required HI and/or SI compensation factors and uses the determined compensation factors to perform calibration of the 3-axis magnetometer 204.

In the embodiment of FIG. 3, if the local B norm and/or magnetic inclination is required, the magnetometer device 302 obtains the local B norm and/or magnetic inclination by determining the longitude/latitude coordinates of the magnetometer device 302 using the GPS circuitry 312 and obtaining the local B norm and/or magnetic inclination corresponding to the determined longitude/latitude from the database 340 (which may be, for example, any one of several online databases).

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

Processing circuitry 106, 122, 206, 222, 306 may be embodied in a number of different ways. In various embodiments, the use of the terms “processor,” “processing circuitry,” “controller,” or “control circuitry” should be understood to include a single core processor, a multi-core processor, multiple processors internal to the illustrated devices, and/or one or more remote or “cloud” processor(s) external to the illustrated devices. In some example embodiments, processing circuitry 106, 122, 206, 222, 306 may include one or more processing devices configured to perform independently. Alternatively, or additionally, processing circuitry 106, 122, 206, 222, 306 may include one or more processor(s) configured in tandem via a bus to enable independent execution of operations, instructions, pipelining, and/or multithreading.

In an example embodiment, the processing circuitry 106, 122, 206, 222, 306 may be configured to execute instructions stored in the memory circuitry 110, 130, 210, 230, 310 or otherwise accessible to the processor. Alternatively, or additionally, the processing circuitry 106, 122, 206, 222, 306 may be configured to execute hard-coded functionality. As such, whether configured by hardware or software methods, or by a combination thereof, processing circuitry 106, 122, 206, 222, 306 may represent an entity (e.g., physically embodied in circuitry) capable of performing operations according to embodiments of the present disclosure while configured accordingly. Alternatively, or additionally, processing circuitry 106, 122, 206, 222, 306 may be embodied as an executor of software instructions, and the instructions may specifically configure the processing circuitry 106, 122, 206, 222, 306 to perform the various algorithms embodied in one or more operations described herein when such instructions are executed. In some embodiments, the processing circuitry 106, 122, 206, 222, 306 includes hardware, software, firmware, and/or a combination thereof that performs one or more operations described herein.

In some embodiments, the processing circuitry 106, 122, 206, 222, 306 (and/or co-processor or any other processing circuitry assisting or otherwise associated with the processor) is/are in communication with the memory circuitry 110, 130, 210, 230, 310 via a bus for passing information among components of the illustrated devices.

Memory or memory circuitry 110, 130, 210, 230, 310 may be non-transitory and may include, for example, one or more volatile and/or non-volatile memories. In some embodiments, the memory circuitry 110, 130, 210, 230, 310 includes or embodies an electronic storage device (e.g., a computer readable storage medium). In some embodiments, the memory circuitry 110, 130, 210, 230, 310 is configured to store information, data, content, applications, instructions, or the like, for enabling the illustrated devices to carry out various operations and/or functions in accordance with example embodiments of the present disclosure.

Communications circuitry 108, 128, 208, 228, 308 may be included in the illustrated devices. The communications circuitry 108, 128, 208, 228, 308 may include any means such as a device or circuitry embodied in either hardware or a combination of hardware and software that is configured to receive and/or transmit data from/to a network and/or any other device, circuitry, or module in communication with the illustrated devices. In some embodiments the communications circuitry 108, 128, 208, 228, 308 includes, for example, a network interface for enabling communications with a wired or wireless communications network. Additionally or alternatively, the communications circuitry 108, 128, 208, 228, 308 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 108, 128, 208, 228, 308 may include circuitry for interacting with an antenna(s) and/or other hardware or software to cause transmission of signals via the antenna(s) and/or to handle receipt of signals received via the antenna(s). In some embodiments, the communications circuitry 108, 128, 208, 228, 308 enables transmission to and/or receipt of data from a user device, one or more sensors, and/or other external computing device(s) in communication with the illustrated devices.

Various compensation algorithms for the various cases introduced above will now be described in detail. As described above, these algorithms may be performed by the processing circuitry 122 of the calibration device 120 of FIG. 1, the processing circuitry 206 of the magnetometer device 202 of FIG. 2, or the processing circuitry 306 of the magnetometer device 302 of FIG. 3. All of the algorithms described below begin with rotating the magnetometer device in two dimensions about a fixed axis of rotation (vertical in Cases 1-3 and any orientation in Cases 4-6) and collecting magnetic field data.

### Case 1—Vertical Rotation Axis, HI (Offset) Compensation Only

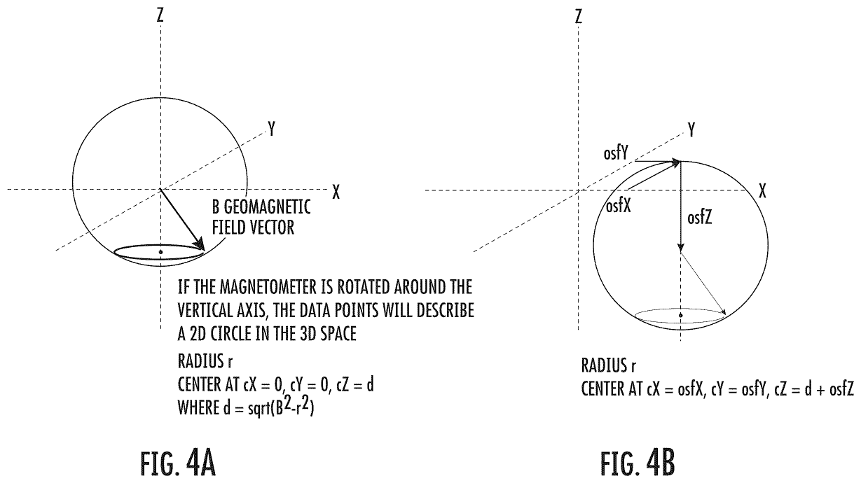

FIG. 4A is a 3D view of a circle described by magnetic data points collected during rotation of a magnetometer to be calibrated about a fixed vertical axis (i.e., the Z axis), without any HI or SI effects (i.e., an ideal or expected circle). FIG. 4B is a 3D view of a circle described by magnetic data points collected during rotation of a magnetometer to be calibrated about a fixed vertical axis, with an offset in the X-direction (OfsX), an offset in the Y-direction (OfsY), and an offset in the Z-direction (OfsZ) caused by HI effects.

In Case 1 with only HI effects to be compensated, the magnetic field data points collected describe a circle in the horizontal plane, that is they all have the same Z coordinate. A circle can be fit to the XY coordinates to compute the radius r and the coordinates cX, cY, cZ of its center.

When there are no measurement errors (i.e., no HI effects), the center of the circle will have coordinates cX=0, cY=0, and cZ=d where d=sqrt(B\hat{ }2−r\hat{ }2), where B is the norm of the local geomagnetic field and r is the radius of the circle. When HI effects are present, the center of the circle will have coordinates cX=0+OfsX, cY=0+OfsY, cZ=d+OfsZ. From this it can be determined that the wanted offset can be computed as OfsX=cX, OfsY=cY, OfsZ=cZ−d.

In various embodiments, the calibration procedure for Case 1 is as follows: check that all the collected magnetic field data points have the same Z coordinate (this indicates that the rotation axis is vertical as required in this case) (this may be assumed if the magnetometer device is known to be mounted on a vertical pole); fit a circle to the XY coordinates of the magnetic field data points, using any suitable circle-fitting algorithm (the output of the circle fitting is a radius r and center coordinates cX, cY (cZ is the Z coordinate of the data points); compute the HI offset to be subtracted using OfsX=cX, OfsY=cY, and OfsZ=cZ−d, where d=sqrt(B\hat{ }2−r\hat{ }2). Note that OfsZ can only be computed if the norm B of the local geomagnetic field is available. However, from the point of view of an e-compass application, OfsZ is only needed when roll and pitch angles are not zero. Therefore, if roll and pitch are both zero, B norm is not needed for a successful calibration and compensation of the magnetometer. OfsX and OfsY will be computed correctly and will be subtracted as needed to support the computation of the yaw angle.

### Case 2—Vertical Rotation Axis, HI (Offset) and Diagonal of SI (Scaling Factors) Compensation

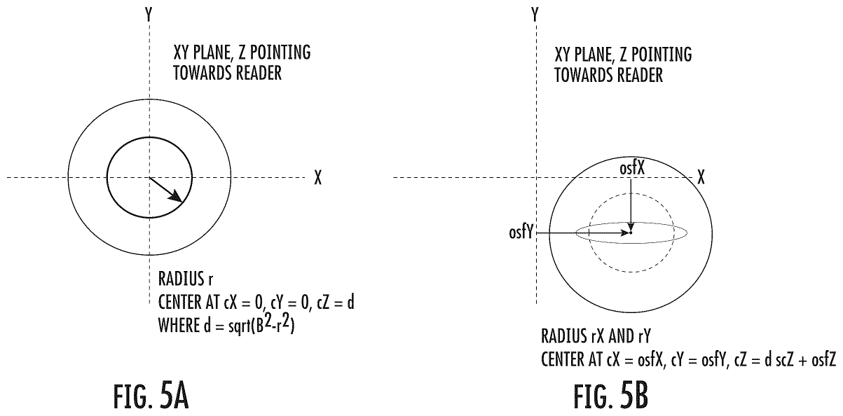

FIG. 5A is a 3D view of a circle described by magnetic data points collected during rotation of a magnetometer to be calibrated about a fixed vertical axis (i.e., the Z axis), without any HI or SI effects (i.e., an ideal or expected circle). FIG. 5B is a 3D view of an ellipse described by magnetic data points collected during rotation of a magnetometer to be calibrated about a fixed vertical axis. SI scaling factors have transformed the ideal circle of FIG. 5A into the ellipse of FIG. 5B, with an offset in the X-direction (OfsX), an offset in the Y-direction (OfsY), and an offset in the Z-direction (OfsZ) caused by HI effects.

In Case 2 with only HI and SI (scaling) effects to be compensated, the magnetic field data points collected describe an ellipse in the horizontal plane, that is they all have the same Z coordinate. An ellipse can be fit to the XY coordinates to compute the radius rX and rY, and the coordinates cX, cY, cZ of its center.

When there are no measurement errors, the data points will be in the 2D circle with radius r, in the horizontal plane Z=d (d is defined above). The effect of the scaling factors scX, scY, scZ will transform the circle in the ellipse with radiuses rX=r scX, rY=r scY, in the horizontal plane: Z=d scZ+OfsZ. From this, it can be determined that the scaling factors can be computed as scX=rX/r, scY=rY/r. The radius r can be directly computed from the norm B and the magnetic inclination with respect to the horizontal plane.

If the norm B or the magnetic inclination or both are not available, a reference r can be utilized. It will be proportional to the actual r: reference r=actual r*scaling factors. In other words, an arbitrary r can be selected and used to compute the scaling factors. From the point of view of the e-compass application the common scaling factor or unit of measurement does not matter.

Note that there is not enough information to compute scZ and OfsZ which both affects the coordinate Z, as there are two unknowns (scZ and OfsZ) but only one equation. However, from the point of view of the e-compass application, when roll and pitch are both zero, MagZ measurements are not used and therefore need not be compensated for offset and scaling errors.

In various embodiments, the calibration procedure for Case 2 is as follows: check that all the collected magnetic field data points have the same Z coordinate (this indicates that the rotation axis is vertical as required in this case) (this may be assumed if the magnetometer device is known to be mounted on a vertical pole); fit an ellipse to the XY coordinates of the magnetic field data points using any suitable ellipse-fitting algorithm (the output of the ellipse fitting is an ellipse with radius rX, rY and center coordinates cX, cY (cZ is the Z coordinate of the data points), and compute the scaling factors to be applied as: scX=rX/r and scY=rY/r (scZ cannot be computed). The radius r can be any arbitrary reference radius or the true expected radius based on the local magnetic field strength B and on the magnetic inclination (angle with respect to horizontal plane).

Once scaling factors are compensated, one can apply the HI offset algorithm described above in Case 1 to compensate for the HI offset. Alternatively, the HI offsets can be calculated directly as: OfsX=cX/scX and OfsY=cY/scY (OfsZ cannot be computed).

### Case 3—Vertical Rotation Axis, HI (Offset) and Full SI (Scaling and Rotation) Compensation

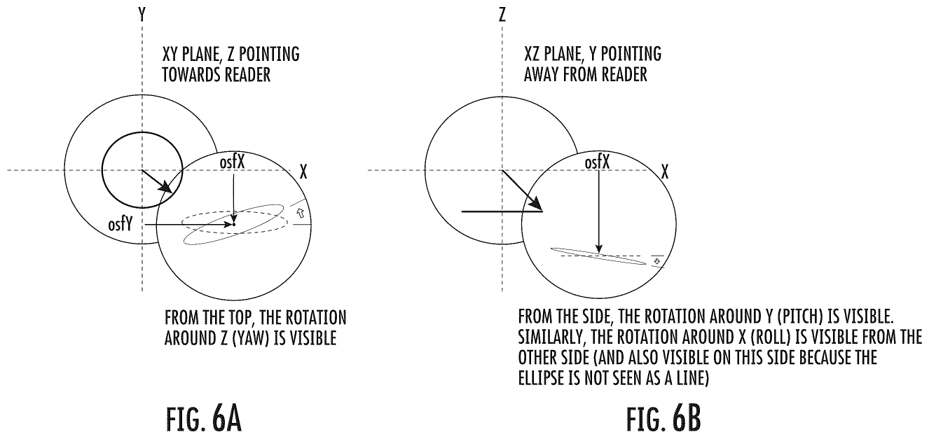

The left side of FIG. 6A is a top (along the Z axis) 3D view of a circle described by magnetic data points collected during rotation of a magnetometer to be calibrated about a fixed vertical axis (i.e., the Z axis), without any HI or SI effects (i.e., an ideal or expected circle). The left side of FIG. 6B is a side view (along the Y axis) of the ideal circle shown on the left side of FIG. 6A.

The right side of FIG. 6A is a top 3D view of an ellipse described by magnetic data points collected during rotation of a magnetometer to be calibrated about a fixed vertical axis. SI scaling factors have transformed the ideal circle of the left side of FIG. 6A into an ellipse and SI rotation has rotated the ellipse around the Z-axis (yaw). The right side of FIG. 6B is a side view of the ellipse of the right side of FIG. 6A, also showing rotation about the X-axis (roll) and the Y-axis (pitch). There is also an offset in the X-direction (OfsX), an offset in the Y-direction (OfsY), and an offset in the Z-direction (OfsZ) caused by HI effects.

In Case 3 with HI, SI (scaling), and SI (rotation) effects to be compensated, the magnetic field data points collected describe a rotated ellipse which is not in the horizontal plane, that is they do not all have the same Z coordinates. In various embodiments, the plane of the ellipse can be identified in several ways (e.g., least-square fitting of plane equation) and a de-rotation from this plane to a horizontal plane can be applied to the magnetic field data points. This is one of the cases where the user needs to confirm that the rotation axis is indeed vertical or a tilt sensor is needed to confirm this, because the magnetic field data appearing to be on a tilted plane could alternatively correspond to Case 4 (below). Discriminating Case 3 from Case 4 can be done by confirming the rotation axis. The de-rotation will compensate for roll and pitch rotations. After the de-rotation to the horizontal plane, any suitable fit algorithm can be applied to identify the rotated ellipse that matches the XY de-rotated data points. This ellipse can be de-rotated so that the major and minor axis are aligned with the X and Y axis. This de-rotation compensates for the yaw rotation. The de-rotation matrix has three degrees of freedom for roll, pitch, and yaw angles. Two angles comes from the 2D plane fitting, roll and pitch, and one angle comes from the rotated ellipsoid fitting, yaw.

The original ellipse has the major and minor axes not aligned with the X and Y axes, while the de-rotated ellipse does have the major and minor axes aligned with the X and Y axes. The identified roll, pitch, and yaw angle completely determine the de-rotation matrix with three degrees of freedom.

In various embodiments, the calibration procedure for Case 3 is as follows: fit a plane to the magnetic field data points obtaining the coefficients of the normal to the identified plane (expressed as a, b, c) (using any suitable plane fitting algorithm); de-rotate the magnetic field data points to the horizontal plane; fit a rotated ellipse to the XY coordinates of the magnetic field data points using any suitable ellipse-fitting algorithm (the output of the ellipse fitting is an ellipse with radiuses r1, r2 (not aligned with X and Y axes), center coordinates cX, cY, and a 2D rotation matrix (the columns in this matrix are the radiuses direction which can be combined with the magnitude above); rotate the ellipse back to original tilted plane such that the center coordinates are now cX, cY, cZ and the radiuses are now 3D vectors; and compute the de-rotation matrix needed to align the radiuses and the normal to the XY axes and the vertical respectively.

After the roll/pitch/yaw de-rotation and computation of the de-rotation matrix, the algorithm described above in Case 2 can be used to determine the SI scaling factors and the algorithm described above in Case 1 can be used to determine the HI offsets. Alternatively, the center of the fitted ellipse determined in Case 3 can be utilized to directly determine the HI offsets and radiuses (3D vectors) of the 3D fitted ellipse can be used to determine the SI scaling factors and rotation.

### Case 4—Generic Rotation Axis, HI (Offset) Compensation Only

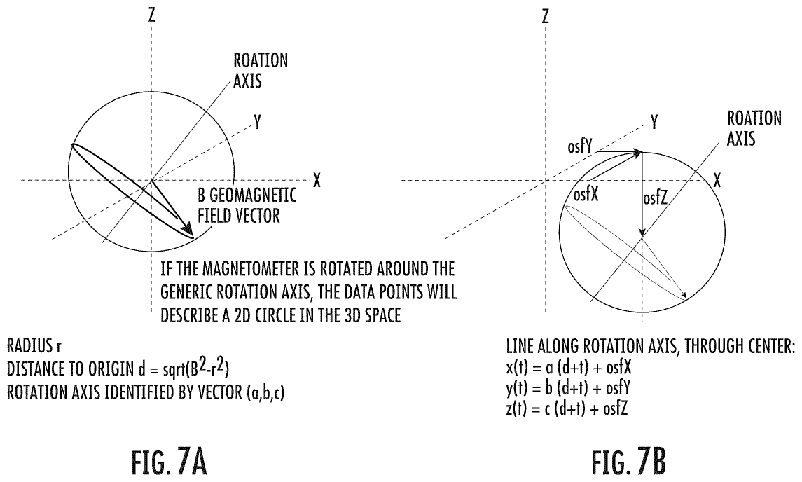

FIG. 7A is a 3D view of a circle described by magnetic data points collected during rotation of a magnetometer to be calibrated about a fixed non-vertical axis, without any HI or SI effects (i.e., an ideal or expected circle). FIG. 7B is a 3D view of a circle described by magnetic data points collected during rotation of a magnetometer to be calibrated about a fixed non-vertical axis, with an offset in the X-direction (OfsX), an offset in the Y-direction (OfsY), and an offset in the Z-direction (OfsZ) caused by HI effects.

In Case 4 with only HI effects to be compensated, the magnetic field data points collected describe a circle in a tilted plane. The normal of the tilted plane corresponds to the rotation axis. In various embodiments, if the rotation axis information is not available, the tilted plane of the magnetic data points can be identified in several ways (e.g., least-square fitting of plane equation) and a de-rotation from this plane to a horizontal plane can be applied to the magnetic data points. In various embodiments, if there is a tilt sensor in the system, this additional sensor can be utilized to double check the information obtained by fitting a plane to the magnetic field data.

In various embodiments, after the de-rotation to the horizontal plane, any suitable circle-fitting algorithm can be utilized to identify a circle that matches the de-rotated magnetic data points and the circle can be rotated back to the tilted plane. This enables computation of the radius and the center coordinates of the tilted circle. In various embodiments, the distance d to the origin can be computed from the radius and the norm B of the magnetic field as: d=sqrt(B\hat{ }2−r\hat{ }2).

The normal to the tilted plane, which is the same as the rotation axis, corresponds to a 3-element unity vector (expressed as a, b, c). The line along the rotation axis which passes through the center of the circle has the equation: xyz(t)=abc*(d+t). The center of the circle is obtained by setting t=0:cX′=a*d, cY′=b*d, cZ′=c*d. This is the expected value for the coordinates of the center. The expected value can be computed from d and from (a, b, c).

If there are HI effects, then the center will be translated to the following coordinates: cX″=cX′+OfsX, cY″=cY′+OfsY, cZ″=cZ′+OfsZ. This is the actual value of the coordinates of the center. The actual value is computed directly as described above (rotate the magnetic field data points to the horizontal 2D plane, circle fitting, and de-rotation back to tilted plane).

As an example, consider the equation for the X coordinate of the center: cX=a*d+OfsX. If B is known, d can be calculated and therefore OfsX can be exactly calculated using: OfsX=cX−a*d. If B is not known, an estimated or average value of B can be used to calculate a reasonable approximation of d. For example, the average value of B for the region in which the magnetometer device is to be installed may be used.

It should be noted that the difference between the actual and the expected value for each coordinate of the center of the circle is exactly the wanted offset to be subtracted to compensate for the HI effects.

It should be noted that when a, b, or c is 0, then the computation of the expected value for the corresponding coordinate does not depend on the distance d, and therefore does not require the knowledge of the norm B of the local magnetic field. The expected value for that coordinate will be 0. For example, consider a vertical rotation axis with a 3-element unity vector of (0,0,1), hence a=0, b=0, c=1. The expected value for the center coordinates is cX′=a*d=0; cY′=b*d=0; cZ′=c*d=d. As can be seen, only cZ depends on d.

### Case 5-Generic Rotation Axis, HI (Offset) and Diagonal of SI (Scaling Factors) Compensation

In Case 5 with HI and SI (scaling) effects to be compensated, the magnetic field data points collected describe an ellipse in a tilted plane. Note that in this case the normal of the tilted plane does not correspond to the rotation axis and knowledge of the rotation axis is required. This is the case where an optional tilt sensor may be needed.

In various embodiments, the tilted plane of the ellipse can be identified in several ways (e.g., least-square fitting of plane equation) and a de-rotation from the tilted plane to a horizontal plane can be applied to the magnetic data points. After the de-rotation to the horizontal plane, any suitable ellipse-fitting algorithm can be utilized to identify the ellipse that matches the de-rotated data. Then the ellipse can be rotated back to the tilted plane. This is how the actual ellipse is identified.

In various embodiments, the expected circle can be identified by performing a rotation of the local earth magnetic field vector around the rotation axis. This requires the knowledge of the B norm and inclination with respect to the horizontal plane.

The volume and dimensions of a bounding box around the tilted ellipse (width W″, height H″, depth D″) is affected by the scaling factors (sX, sY, sZ). As such, in various embodiments the scaling factor for each axis corresponds to the ratio of the corresponding dimension of the bounding box around the tilted ellipse to the corresponding dimension of a bounding box around the ideal tilted circle (width W′, height H′, depth D′). The dimensions of the bounding box around the tilted ellipse can be expressed as: width W″=W′*sX; height H″=H′*sZ; depth D″=D′*sY. Thus, the scaling factors can be determined as follows: sX=W″/W′; sZ=H″/H′; sY=D″/D′.

In various embodiments, the dimensions of the bounding box around the tilted ellipse can be computed efficiently in a straightforward manner from the identified parameters of the ellipse. Alternatively, it is possible to compute many points along the ellipse and find the max/min of the coordinates of those points. The latter method is simpler but the accuracy depends on how many points are computed and is therefore not memory or computation efficient. The former method is more complex to derive but results in few computations that return an accurate result.

It should be noted that the ratio cannot be computed when the denominator is zero. Therefore, depending on the direction of the rotation axis some scaling factor may not be computable. For example, if the rotation axis is around the vertical, the expected height is 0 and therefore the scaling factor for Z is not computable.

In various embodiments, after the scaling factors are determined, the HI offsets can be determined as described in Case 4.

### Case 6—Generic Rotation Axis, HI (Offset) and Full SI (Scaling and Rotation) Compensation

In Case 5 with HI, SI (scaling), and SI (rotation) effects to be compensated, the magnetic field data points collected describe a rotated ellipse in a tilted plane. Note that in this case the normal of the tilted plane does not correspond to the rotation axis and knowledge of the rotation axis is required. This is the case where an optional tilt sensor may be needed.

In various embodiments, the tilted plane of the ellipse can be identified in several ways (e.g., least-square fitting of plane equation) and a de-rotation from the tilted plane to a horizontal plane can be applied to the magnetic data points. After the de-rotation to the horizontal plane, any suitable ellipse-fitting algorithm can be utilized to identify the ellipse that matches the de-rotated data. Then the ellipse can be rotated back to the tilted plane. This is how the actual ellipse is identified.

In various embodiments, the expected circle can be identified by performing a rotation of the local earth magnetic field vector around the rotation axis. This requires the knowledge of the B norm and inclination with respect to the horizontal plane.

Unlike in Case 5 above, if one scales the axes to match the actual volume of a bounding box occupied by the rotated ellipse to the expected volume (i.e., the volume of the bounding box of the ideal circle), the tilted plane will not correspond to the expected tilted plane and/or the ellipse is not resized into a circle as it should be. This is caused by the additional rotation which is present in the measurements (SI rotation effect). When the correct derotation is applied before scaling, the tilted plane of the de-rotated and scaled data will match the expected plane indicated by the rotation axis.

A simple but inefficient way to find the correct derotation is by trial-and-error. In various embodiments, the magnetic field data is de-rotated, then the scaling algorithm of Case 5 is applied, and then it is determined whether the resulting tilted plane matches what is indicated by the rotation axis and whether the ellipse has become a circle as expected (e.g., the distance from points along the perimeter to the center is constant). Different de-rotation matrices can be tried in a trial-and-error fashion, using a search strategy to increase the speed of convergence to the correct solution. In various embodiments, this is similar to the so-called “Procrustes problem” where one seeks the transformation needed to map a set of points or vectors (the tilted ellipse from the magnetic field measurements) to another set of points or vectors (the tilted expected ideal circle). For the search strategy, one can compute the effect of each parameters (coefficients of the rotation matrix for example, or components of the equivalent quaternion), and then perform gradient descent where one applies the modification required to reduce and minimize the loss function. That is, one computes the partial derivatives of the loss function and uses them to estimate the new set of parameters.

In various embodiments, after the derotation has been performed, the scaling factors can be determined as described in Case 5 and the HI offsets can be determined as described in Case 4.

### Applications

Various embodiments of the present disclosure may be applied in application in which a magnetometer, after installation, can only perform a rotation around a single axis such that no 3D motion can be performed to apply the conventional magnetometer calibration algorithm. One example application is for use with doors which can only rotate around a vertical axis and windowpanes which can only rotate around a vertical or a horizontal axis to compute the opening angle, in which the yaw/heading in the open and closed positions can be utilized to support the detection of the state (open or closed). Another example application is communication antennas mounted on poles. In such applications, it may be necessary to compute the yaw/heading for accurate orientation and successful and efficient communication.

Calibration of the magnetometer is required after installation because the metal frame of the body on which the sensor is installed does affect the sensing of the earth magnetic field. In these example applications, roll and pitch are always zero, and yaw/heading can be computed after performing the 2D calibration algorithm of embodiments of the present disclosure.

### System Options

In various embodiments, a mechanical actuator may be used such that the rotation around the single axis can be executed manually or controlled by a dedicated actuator. When an actuator is utilized, care must be taken to de-energize the actuator so there are not high currents that may generate interfering magnetic fields. For better accuracy, it is better to wait for the sensor to be perfectly still in the given orientation, then take several measurements and average them together.

In various embodiments, the magnetometer may be coupled with an optional tilt sensor, such as an accelerometer, to confirm the actual rotation axis. Otherwise, the installer needs to check/confirm manually the direction of the rotation axis by other means. In various embodiments, the cases where the tilt sensor is not needed are: (1) when SI effects are not present (Cases 1 and 4), or (2) when the magnetic field data is on the XY or YZ or XZ plane (the most important case is the XY or horizontal plane) and there are only scaling factors and no rotation effects from the soft-iron matrix (this be because scaling factors do not change the tilt in this case) (Cases 1 and 2). Such a tilt sensor can be present in either a magnetometer device (e.g., device 102 in FIG. 1, device 202 in FIG. 2, or device 302 in FIG. 3) or a calibration device (e.g., device 120 in FIG. 1 or device 220 in FIG. 2). In such embodiments, the rotation axis information may be sent between devices where this is needed.

In various embodiments, a rotation sensor or an angular rate sensor (gyroscope) may be included to confirm the amount of the rotation. This additional information is not strictly needed to complete the calibration process but can be useful in many ways. For example, this information may be used to give feedback to the technician who is executing the calibration, letting the technician know when the amount of rotation is enough.

Various methods described herein may provide various technical benefits and improvements. It is noted that processes described herein may be implemented by various means such as hardware, firmware, circuitry and/or other devices associated with execution of software including one or more computer program instructions. For example, one or more of the procedures described herein may be embodied by computer program instructions, which may be stored by a non-transitory memory of an apparatus employing an embodiment of the present disclosure and executed by a processor in the apparatus. These computer program instructions may direct a computer or other programmable apparatus to function in a particular manner, such that the instructions stored in the computer-readable storage memory produce an article of manufacture, the execution of which implements the function specified in the flowchart block(s).

As described above and as will be appreciated based on this disclosure, embodiments of the present disclosure may be configured as methods, mobile devices, backend network devices, and the like. Accordingly, embodiments may comprise various means including entirely of hardware or any combination of software and hardware. Furthermore, embodiments may take the form of a computer program product on at least one non-transitory computer-readable storage medium having computer-readable program instructions (e.g., computer software) embodied in the storage medium. Similarly, embodiments may take the form of a computer program code stored on at least one non-transitory computer-readable storage medium. Any suitable computer-readable storage medium may be utilized including non-transitory hard disks, CD-ROMs, flash memory, optical storage devices, or magnetic storage devices.

### Conclusion

Many modifications and other embodiments of the disclosures set forth herein will come to mind to one skilled in the art to which these disclosures pertain having the benefit of teachings presented in the foregoing descriptions and the associated drawings. Although the figures only show certain components of the apparatus and systems described herein, it is understood that various other components may be used in conjunction with the system. Therefore, it is to be understood that the disclosures are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. The disclosed embodiments relate primarily to fragmented wideband tympanometry techniques for true wireless stereo, however, one skilled in the art may recognize that such principles may be applied to any audio device. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the disclosure(s) set out in any claims that may issue from this disclosure.

While this detailed description has set forth some embodiments of the present disclosure, the appended claims cover other embodiments of the present disclosure which differ from the described embodiments according to various modifications and improvements. For example, the appended claims can cover any form of device or application which uses a magnetometer and whose movement is limited to two dimensions. Such devices and applications may include, but are not limited to, any of the following:
1. Consumer Electronics and Wearables, such as Smartphones, Tablets, and Wearable Devices, for enhancing navigation, augmented reality, and fitness tracking.
2. Automotive and Transportation, such as In-Vehicle Systems and Autonomous Vehicles, for improving navigation and control systems in cars, drones, and unmanned aerial vehicles (UAVs).
3. Industrial and Robotics, such as Autonomous Robots and Industrial Equipment, for enhancing navigation and accuracy in manufacturing, warehousing, and asset tracking.
4. Marine and Aviation, such as Navigation Systems for Marine and Aviation, for improving accuracy in boats, ships, and aircraft.
5. Smart Home and Security, such as Home Automation and Security Systems, for providing precise orientation for smart locks, security cameras, and automated devices.
7. Agriculture, such as Precision Farming Equipment, for improving navigation and efficiency in agricultural machinery.
8. Military and Defense, such as Navigation and Surveillance Systems, for providing accurate heading data for military vehicles and surveillance equipment.

Within the appended claims, unless the specific term “means for” or “step for” is used within a given claim, it is not intended that the claim be interpreted under 35 U.S.C. 112, paragraph 6.

What is claimed is:

1. A method for calibrating a 3-axis magnetometer, the method comprising:
receiving magnetic field data collected as a magnetometer is moved in only two dimensions in a circle or a partial circle around a fixed vertical axis of rotation, the magnetic field data collected at a plurality of locations along the circle or the partial circle;
if only hard iron (HI) offset compensation of the magnetometer is desired, the method comprises:
(a) fitting a circle to the magnetic field data;
(b) determining an X coordinate and a Y coordinate of a center of the fitted circle; and
(c) providing the X coordinate and the Y coordinate of the center of the fitted circle to the magnetometer for use as, respectively, an X-axis HI offset and a Y-axis HI offset for performing HI offset compensation;
if only HI offset compensation and soft iron (SI) scaling compensation are desired, the method comprises:
(a) fitting an ellipse to the magnetic field data;
(b) determining an X coordinate and a Y coordinate of a center of the fitted ellipse;
(c) determining an X-axis scaling factor and a Y-axis scaling factor;
(d) providing the X-axis scaling factor and the Y-axis scaling factor to the magnetometer for performing SI scaling compensation;
(e) using the X-axis scaling factor and the Y-axis scaling factor to determine an X-axis HI offset and a Y-axis HI offset; and
(f) providing the X-axis HI offset and the Y-axis HI offset to the magnetometer for performing HI offset compensation.

2. The method of claim 1, wherein, if HI offset compensation, SI scaling compensation, and SI rotation compensation are desired, the method further comprises, prior to determining an X coordinate and a Y coordinate of a center of the fitted ellipse:
fitting a plane to the magnetic field data;
de-rotating the magnetic field data to a horizontal plane;
fitting an ellipse to the magnetic field data de-rotated to the horizontal plane, and
aligning a minor axis and a major axis of the fitted ellipse to an X-axis and a Y-axis.

3. The method of claim 1, further comprising determining an X-axis radius and a Y-axis radius of the fitted ellipse;
wherein determining the X-axis scaling factor comprises dividing r by the X-axis radius;
wherein determining the Y-axis scaling factor comprises dividing r by the Y-axis radius; and
wherein r is an arbitrary reference radius or r is a true expected radius based on a magnetic field strength and on a magnetic inclination at a location of the magnetometer.

4. The method of claim 1, wherein using the X-axis scaling factor and the Y-axis scaling factor to determine an X-axis HI offset and a Y-axis HI offset comprises:
applying the X-axis scaling factor and the Y-axis scaling factor to the fitted ellipse to obtain a corresponding offset circle; and
determining an X coordinate and a Y coordinate of a center of the corresponding offset circle;
wherein the X coordinate and the Y coordinate of the center of the corresponding offset circle is provided to the magnetometer for use as, respectively, an X-axis HI offset and a Y-axis HI offset for performing HI offset compensation.

5. The method of claim 1, wherein using the X-axis scaling factor and the Y-axis scaling factor to determine an X-axis HI offset and a Y-axis HI offset comprises:
dividing the X coordinate of the center of the fitted ellipse by the X-axis scaling factor to determine the X-axis HI offset; and
dividing the Y coordinate of the center of the fitted ellipse by the Y-axis scaling factor to determine the Y-axis HI offset.

6. The method of claim 1, wherein collecting magnetic field data at a plurality of locations along the circle or the partial circle comprises collecting a plurality of magnetic field data points at each of one or more of the plurality of locations along the circle or the partial circle and averaging the plurality of magnetic field data points collected at each of the one or more of the plurality of locations along the circle or the partial circle.

7. A method for calibrating a 3-axis magnetometer, the method comprising:
(i) receiving magnetic field data collected as a magnetometer is moved in only two dimensions in a circle or a partial circle around a fixed, non-vertical axis of rotation, the magnetic field data collected at a plurality of locations along the circle or the partial circle;
(ii) if only hard iron (HI) offset compensation of the magnetometer is desired, the method comprises:
(a) fitting a plane to the magnetic field data;
(b) de-rotating the magnetic field data to a horizontal plane;
(c) fitting a circle to the magnetic field data de-rotated to the horizontal plane;
(d) determining a radius of the fitted circle;
(e) determining an X coordinate, a Y coordinate, and a Z coordinate of a center of the fitted circle;
(f) rotating the fitted circle back to its original plane;
(f) determining a 3-element unity vector corresponding to a normal of the original plane, the 3-element unity vector comprising a, b, and c elements;
(g) if a magnetic field strength at a location of the magnetometer is known, determining an X-axis HI offset, a Y-axis HI offset, and a Z-axis HI offset using the 3-element unity vector corresponding to the normal of the original plane and the magnetic field strength at the location of the magnetometer;
(h) if a magnetic field strength at a location of the magnetometer is not known, determining an X-axis HI offset, a Y-axis HI offset, and a Z-axis HI offset using the 3-element unity vector corresponding to the normal of the original plane and an estimate of the magnetic field strength at the location of the magnetometer; and
(i) providing the X-axis HI offset, the Y-axis HI offset, and the Z-axis HI offset to the magnetometer for performing HI offset compensation;
(iii) if only HI offset compensation and soft iron (SI) scaling compensation are desired, the method comprises:
(a) fitting a plane to the magnetic field data;
(b) de-rotating the magnetic field data to a horizontal plane;
(c) fitting an ellipse to the magnetic field data;
(d) determining an X coordinate and a Y coordinate of a center of the fitted ellipse;
(e) determining a major axis radius and a minor axis radius of the fitted ellipse;
(f) rotating the fitted ellipse back to its original plane;
(g) determining a height, width, and depth of a bounding box around the fitted ellipse rotated back to its original plane;
(h) determining a height, width, and depth of an ideal bounding box using the magnetic field strength at the location of the magnetometer;
(i) determining an X-axis scaling factor, a Y-axis scaling factor, and a Z-axis scaling factor based on dividing, respectively, the height, width, and depth of the bounding box around the fitted ellipse rotated back to its original plane by the height, width, and depth of the ideal bounding box;
(j) providing the X-axis scaling factor, the Y-axis scaling factor, and the Z-axis scaling factor to the magnetometer for performing SI scaling compensation;
(k) using the X-axis scaling factor, the Y-axis scaling factor, and the Z-axis scaling factor to determine an X-axis HI offset, a Y-axis HI offset, and a Z-axis HI offset; and
(l) providing the X-axis HI offset, the Y-axis HI offset, and the Z-axis HI offset to the magnetometer for performing HI offset compensation.

8. The method of claim 7, wherein, if HI offset compensation, SI scaling compensation, and SI rotation compensation are desired, the method further comprises, prior to providing the X-axis scaling factor, the Y-axis scaling factor, and the Z-axis scaling factor to the magnetometer for performing SI scaling compensation:
applying the determined X-axis scaling factor, Y-axis scaling factor, and Z-axis scaling factor to the fitted ellipse rotated back to its original plane;
after applying the determined X-axis scaling factor, Y-axis scaling factor, and Z-axis scaling factor to the fitted ellipse rotated back to its original plane, determining if a resulting shape is a circle on the original plane; and
if the resulting shape is not a circle and/or is not on the original plane, applying one or more correction factors to the determined X-axis scaling factor, Y-axis scaling factor, and Z-axis scaling factor, reapply the determined X-axis scaling factor, Y-axis scaling factor, and Z-axis scaling factor to the fitted ellipse rotated back to its original plane, and redetermine if the resulting shape is a circle on the original plane.

9. The method of claim 7, wherein determining an X-axis HI offset, a Y-axis HI offset, and a Z-axis HI offset using the 3-element unity vector corresponding to the normal of the original plane and the magnetic field strength at the location of the magnetometer comprises:
(i) determining a distance (d) to an origin using d=sqrt(B\hat{ }2−r\hat{ }2), where B is the magnetic field strength at the location of the magnetometer and r is the radius of the fitted circle;
(ii) determining an X-axis HI offset (OfsX) using OfsX=cX−a*d, where cX is the X coordinate of the center of the fitted circle and a is an a element of the 3-element unity vector corresponding to the normal of the original plane;
(iii) determining a Y-axis HI offset (OfsY) using OfsY=cY-c*d, where cY is the Y coordinate of the center of the fitted circle and b is a b element of the 3-element unity vector corresponding to the normal of the original plane; and
(iv) determining a Z-axis HI offset (OfsZ) using OfsZ=cZ−c*d, where cZ is the Z coordinate of the center of the fitted circle and c is a c element of the 3-element unity vector corresponding to the normal of the original plane.

10. The method of claim 7, wherein determining an X-axis HI offset, a Y-axis HI offset, and a Z-axis HI offset using the 3-element unity vector corresponding to the normal of the original plane and an estimate of the magnetic field strength at the location of the magnetometer comprises:
(i) determining a distance (d) to an origin using d=sqrt(B-est\hat{ }2−r\hat{ }2), where B-est is the estimated magnetic field strength at the location of the magnetometer and r is the radius of the fitted circle;
(ii) determining an X-axis HI offset (OfsX) using OfsX=cX−a*d, where cX is the X coordinate of the center of the fitted circle and a is the a element of the 3-element unity vector corresponding to the normal of the original plane;
(iii) determining a Y-axis HI offset (OfsY) using OfsY=cY−c*d, where cY is the Y coordinate of the center of the fitted circle and b is the b element of the 3-element unity vector corresponding to the normal of the original plane; and
(iv) determining a Z-axis HI offset (OfsZ) using OfsZ=cZ−c*d, where cZ is the Z coordinate of the center of the fitted circle and c is the c element of the 3-element unity vector corresponding to the normal of the original plane.

11. A system for calibrating a 3-axis magnetometer, the system comprising:
a first device comprising processing circuitry configured to:
(i) if only hard iron (HI) offset compensation of the magnetometer is desired, the processing circuitry is configured to:
(a) fit a circle to magnetic field data collected as a magnetometer is moved in only two dimensions in a circle or a partial circle around a fixed vertical axis of rotation;
(b) determine an X coordinate and a Y coordinate of a center of the fitted circle; and
(c) provide the X coordinate and the Y coordinate of the center of the fitted circle to the magnetometer for use as, respectively, an X-axis HI offset and a Y-axis HI offset for performing HI offset compensation; and
(ii) if only HI offset compensation and soft iron (SI) scaling compensation are desired, the processing circuitry is configured to:
(a) fit an ellipse to the magnetic field data;
(b) determine an X coordinate and a Y coordinate of a center of the fitted ellipse;
(c) determine an X-axis scaling factor and a Y-axis scaling factor;
(d) provide the X-axis scaling factor and the Y-axis scaling factor to the magnetometer for performing SI scaling compensation;
(e) use the X-axis scaling factor and the Y-axis scaling factor to determine an X-axis HI offset and a Y-axis HI offset; and
(f) provide the X-axis HI offset and the Y-axis HI offset to the magnetometer for performing HI offset compensation.

12. The system of claim 11, wherein, if HI offset compensation, SI scaling compensation, and SI rotation compensation are desired, the processing circuitry is further configured to, prior to determining an X coordinate and a Y coordinate of a center of the fitted ellipse:
fit a plane to the magnetic field data;
de-rotate the magnetic field data to a horizontal plane;
fit an ellipse to the magnetic field data de-rotated to the horizontal plane, and
align a minor axis and a major axis of the fitted ellipse to an X-axis and a Y-axis.

13. The system of claim 11, wherein the processing circuitry is further configured to determine an X-axis radius and a Y-axis radius of the fitted ellipse;
wherein determining the X-axis scaling factor comprises dividing r by the X-axis radius;
wherein determining the Y-axis scaling factor comprises dividing r by the Y-axis radius; and
wherein r is an arbitrary reference radius or r is a true expected radius based on a magnetic field strength and on a magnetic inclination at a location of the magnetometer.

14. The system of claim 11, wherein using the X-axis scaling factor and the Y-axis scaling factor to determine an X-axis HI offset and a Y-axis HI offset comprises:
applying the X-axis scaling factor and the Y-axis scaling factor to the fitted ellipse to obtain a corresponding offset circle; and
determining an X coordinate and a Y coordinate of a center of the corresponding offset circle;
wherein the X coordinate and the Y coordinate of the center of the corresponding offset circle is provided to the magnetometer for use as, respectively, an X-axis HI offset and a Y-axis HI offset for performing HI offset compensation.

15. The system of claim 11, wherein using the X-axis scaling factor and the Y-axis scaling factor to determine an X-axis HI offset and a Y-axis HI offset comprises:
dividing the X coordinate of the center of the fitted ellipse by the X-axis scaling factor to determine the X-axis HI offset; and
dividing the Y coordinate of the center of the fitted ellipse by the Y-axis scaling factor to determine the Y-axis HI offset.

16. The system of claim 11, wherein collecting magnetic field data at a plurality of locations along the circle or the partial circle comprises collecting a plurality of magnetic field data points at each of one or more of the plurality of locations along the circle or the partial circle and averaging the plurality of magnetic field data points collected at each of the one or more of the plurality of locations along the circle or the partial circle.

17. The system of claim 11, further comprising a second device;
wherein the first device is mounted to the fixed vertical axis;
wherein the second device transmits to the first device a magnetic field strength and a magnetic inclination at a location of the first device.

18. The system of claim 17, wherein the second device comprises processing circuitry and an auxiliary magnetometer configured for performing a 3-D calibration to determine a magnetic field strength and a magnetic inclination at a location of the second device co-located with the first device.

19. The system of claim 17, wherein the second device comprises global positioning system (GPS) circuitry to determine a location of the second device co-located with the first device;
wherein the processing circuitry of the second device is configured for querying an internal or external database to obtain a magnetic field strength and a magnetic inclination at the location of the second device co-located with the first device.

20. The system of claim 11, further comprising a second device;
wherein the second device is mounted to the fixed vertical axis; and
wherein the second device receives the magnetic field data from the first device.
